(19) United States
(12) Patent Application Publication
(10) Pub. No.: US 2012/0148726 A1
(43) Pub. Date: Jun. 14, 2012

(54) ALIGNMENT FILM PRINTING METHOD OF LCD SUBSTRATE AND DEVICE THEREOF

(75) Inventors: Bin LI, Shenzhen (CN); Hsiang-yin SHIH, Shenzhen (CN); Cheng-chuan CHAN, Shenzhen (CN); Wei-chun LEE, Shenzhen (CN); Chengming HE, Shenzhen (CN)

(73) Assignee: SHENZHEN CHINA STAR OPTOELECTRONICS TECHNOLOGY CO., LTD., Shenzhen (CN)

(21) Appl. No.: 13/219,130

(22) Filed: Aug. 26, 2011

(30) Foreign Application Priority Data
Dec. 8, 2010 (CN) 201010579670.5

(51) Int. Cl. C23C 16/52; B05C 11/00

(52) U.S. Cl. 427/8; 118/698

(57) ABSTRACT

Disclosed are an alignment film printing method of LCD panel and device thereof. The method comprises: acquiring position information of one or more defect substrate units of a substrate; delivering the position information to a process management system; delivering the position information to a first alignment film printing apparatus by the process management system; and excluding the alignment film printing operation to the defect substrate units performed by the first alignment film printing apparatus. The benefits of the present invention is to control the back-end processes for excluding steps of the printing operations, the detection and etc to the defect substrate units, accordingly, material cost of alignment film printing can be saved.

### BACKGROUND OF THE INVENTION

1. Field of the Invention

The present invention generally relates to a LCD manufacture field, and more particularly to an alignment film printing method of LCD substrate and device thereof.

2. Description of Prior Art

The thin film transistor (TFT) LCD panel is assembled with a substrate having a color filter (CF) and a fitting substrate having thin film transistors (TFT). The inner faces of the CF substrate and the TFT substrate are both coated with polyimide (PI) alignment films. The alignment film printing methods today can be categorized as two ways: the roller coating and the ink jet coating. The roller coating is mainly applied for the manufacture of the small and medium-scale panels in earlier generation. Recently, the ink jet coating art has become widely used with the rapid development of LCD panel manufacture technology in advance generation.

In the manufacture process of the LCD panels, an uncut large substrate unavoidably includes one or more defect substrate units, due to such as bad etch, foreign matter, etcetera. If the entire large substrate is abandoned thence, a tremendous wastage is created. Therefore, with overall consideration of saving cost, the ink jet coating process may be still performed to the uncut large substrate when the amount of the defect substrate units is not too many. The defect substrate units will not be removed until the cutting process. Obviously, the defect substrate units are still processed before the cutting process in prior art. Therefore, enormous polyimide (PI) alignment film material, liquid crystal material, etcetera is wasted.

In the cost structure of A LCD panel, the material cost may account about 70% of the whole. Therefore, how to reduce the wastage of row material and to raise the utilization percent of row material are problems that the manufacturers of LCD panels have to face with. Thus, the aforesaid row material wastage issues are pressing concerns.

### SUMMARY OF THE INVENTION

Fore solving the aforesaid problems in prior, the present invention provides a printing method of LCD panel to solve the problem of material waste due to the printing operations to the defect substrate units in prior art.

Fore solving the aforesaid problems, the present invention provides a printing method of LCD panel, comprising: acquiring position information of a plurality of substrate units of a substrate, and the plurality of substrate units arrayed in the substrate comprises one or more defect substrate units; delivering the position information to a process management system; delivering the position information to a first alignment film printing apparatus by the process management system, and the first alignment film printing apparatus is employed for performing an alignment film printing operation to the substrate; and excluding the alignment film printing operation to the defect substrate units according to the acquired position information in the step of performing the alignment film printing operation to the substrate with the first alignment film printing apparatus.

As considering a possible technical solution, after the process management system obtains the position information, the method further comprises a step of: confirming whether a proportion of the amount of the defect substrate units in the substrate exceeds a predetermined threshold or not, and if the proportion does not exceed the threshold, then keeping performing the alignment film printing operation to the substrate, if the proportion exceeds the threshold, then stopping performing the alignment film printing operation to the substrate.

As considering a possible technical solution, in the step of delivering the position information to the first alignment film printing apparatus by the process management system, the method further comprises a step of: delivering the position information to a first detection apparatus employed for detecting the process quality of the first alignment film printing apparatus for the first detection apparatus to exclude the detection to the defect substrate units.

As considering a possible technical solution, after the process management system obtains the position information, the method further comprises steps of: delivering the position information to a second alignment film printing apparatus, employed for performing an alignment film printing operation to a fitting substrate corresponding to the substrate; and excluding the alignment film printing operation to the corresponding substrate units of the fitting substrate according to the acquired position information in the step of performing the alignment film printing operation to the fitting substrate with the second alignment film printing apparatus.

As considering a possible technical solution, in the step of delivering the position information to the second alignment film printing apparatus by the process management system, the method further comprises a step of: delivering the position information to a second detection apparatus employed for detecting the process quality of the second alignment film printing apparatus for the second detection apparatus to exclude the detection to unprinted substrate units of the fitting substrate.

The present invention further provides an alignment film printing device of LCD panel, characterized in comprising: an information acquirement module, acquiring position information of a plurality of substrate units of a substrate, and the plurality of substrate units arrayed in the substrate comprises one or more defect substrate units; a first information deliver module, delivering the position information to a process management system; a second information deliver module, employed for the process management system to deliver the position information to a first alignment film printing apparatus and the first alignment film printing apparatus is employed for performing an alignment film printing operation to the substrate; and a first alignment film printing apparatus control module, controlling the first alignment film printing apparatus to exclude the alignment film printing operation to the defect substrate units according to the acquired position information.

As considering a possible technical solution, the device further comprises a yield rate judgment module between the first information deliver module and the second information deliver module, and the yield rate judgment module is employed for confirming whether a proportion of the amount of the defect substrate units in the substrate exceeds a predetermined threshold or not, and if the proportion does not exceed the threshold, then keeping performing the alignment film printing operation to the substrate, if the proportion exceeds the threshold, then stopping performing the alignment film printing operation to the substrate.

As considering a possible technical solution, the second information deliver module further progresses a step of: delivering the position information to a first detection apparatus employed for detecting the process quality of the first alignment film printing apparatus; and the first alignment film printing apparatus further comprises a first detection apparatus control module, controlling the first detection apparatus to exclude the detection to the defect substrate units.

As considering a possible technical solution, after the first information deliver module, the device further comprises: a third information deliver module, employed for delivering the position information to a second alignment film printing apparatus, employed for performing an alignment film printing operation to a fitting substrate corresponding to the substrate; and a second alignment film printing apparatus control module, excluding the alignment film printing operation to the corresponding substrate units of the fitting substrate according to the acquired position information in the step of performing the alignment film printing operation to the fitting substrate with the second alignment film printing apparatus.

As considering a possible technical solution, the third information deliver module further progresses a step of: delivering the position information to a second detection apparatus employed for detecting the process quality of the second alignment film printing apparatus; and the second alignment film printing apparatus further comprises a second detection apparatus control module to exclude the detection to unprinted substrate units of the fitting substrate.

The benefits of the present invention are to control the back-end processes for excluding steps of the printing operations, the detection, etcetera to the defect substrate units by acquiring the position information of the defect substrate units in the substrate and delivering the position information to these back-end apparatuses including the printing apparatuses and the detection apparatuses. Accordingly, material cost of printing can be saved and the process time of the steps of the detection or etc. also can be saved in advance.

### BRIEF DESCRIPTION OF THE DRAWINGS

FIG. 1 shows a flowchart of the first specific embodiment of the method according to the present invention.

FIG. 2 shows a structure diagram of the device employed in the first specific embodiment according to the present invention.

FIG. 3 shows a flowchart of the second specific embodiment of the method according to the present invention.

FIG. 4 shows a structure diagram of the device according to the present invention.

### DETAILED DESCRIPTION OF THE INVENTION

Detail descriptions of the specific embodiments of the printing method of LCD substrate and device thereof provided by the present invention in conjunction with the attached figures are introduced below.

For a better understanding the objective, characteristics and benefits of the present invention, preferable embodiments are illustrated in accordance with the attached figures for further explanation. The specification of the present invention provides kinds of embodiments to explain the technical characteristics of the different implementations of the present invention. The locations of the respective elements in the embodiments are for clearly explaining the content of the present invention but not limitations thereto. Same grades used for indicating elements in the different embodiments are simplifying the explanation but not mentioning the relevance between the different embodiments.

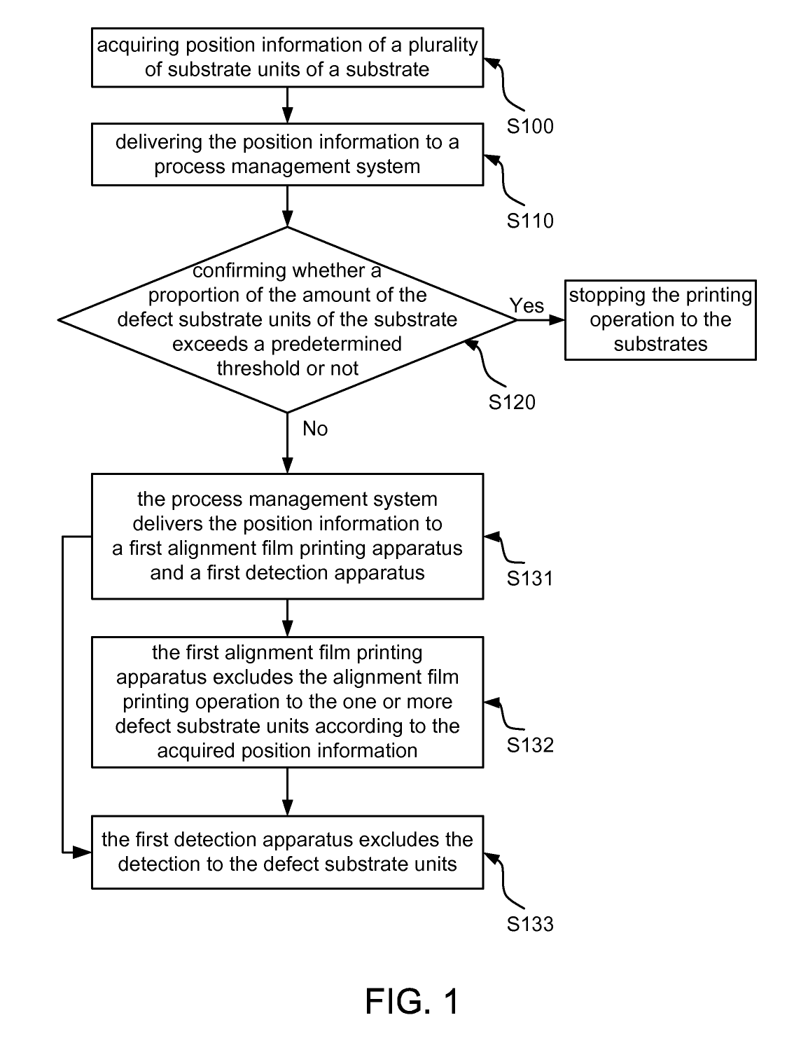

First, introduced is the first specific embodiment of the method according to the present invention. FIG. 1 shows a flowchart of the first specific embodiment of the method according to the present invention. The method comprises the steps below:

Step 100, acquiring position information of one or more defect substrate units of the substrate; Step 110, delivering the position information to a process management system; Step 120, confirming whether a proportion of the amount of the defect substrate units in the substrate exceeds a predetermined threshold or not; Step 131, the process management system delivers the position information to a first alignment film printing apparatus and a first detection apparatus; Step 132, the first alignment film printing apparatus excludes the alignment film printing operation to the one or more defect substrate units according to the acquired position information; Step 133, the first detection apparatus excludes the detection to the defect substrate units.

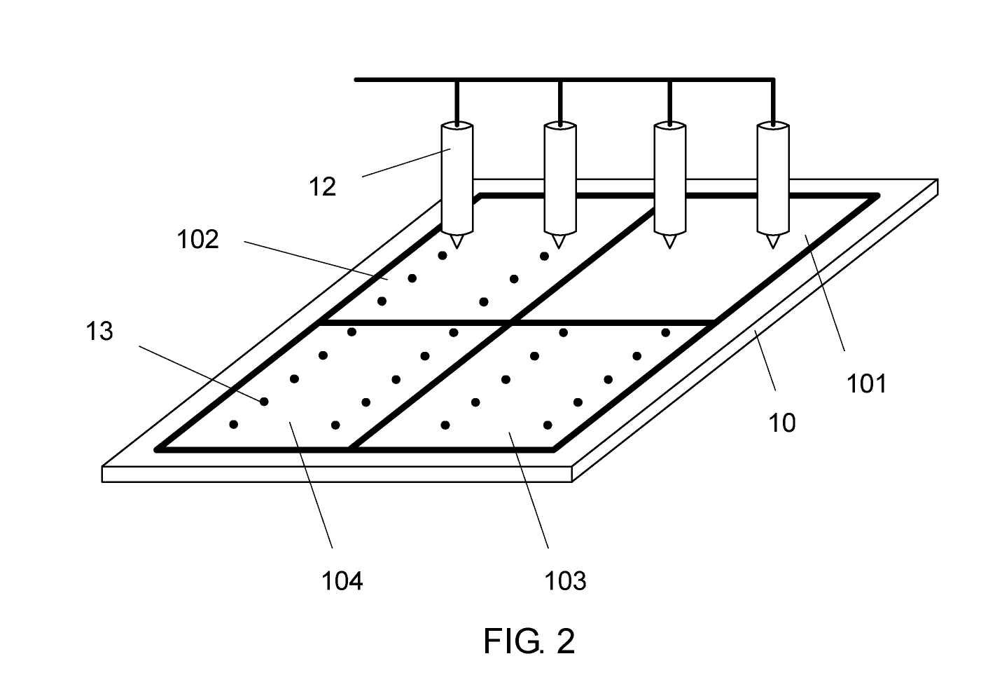

FIG. 2 shows a structure diagram of the device employed in the first specific embodiment according to the present invention. The device comprises substrate 10, a plurality of substrate units 101˜104, a first alignment film printing apparatus 12 and droplets of alignment film material 13.

Then, specifically explain the aforesaid steps individually here below.

In this specific embodiment, the alignment film printing apparatus is a device of performing a polyimide alignment film printing operation on the surface of the substrate. In other embodiment, the printing apparatus can be any other common devices of printing films on the surface of substrate.

Step 100, acquiring position information of a plurality of substrate units of a substrate 10. The substrate comprises a plurality of substrate units arrayed in the entire substrate. Each substrate unit within the substrate can be employed to form a LCD panel after being cut. Please refer to FIG. 2, the substrate 10 comprises four substrate units, respectively indicated 101˜104. In the manufacture processes of the LCD panel, one or more defect substrate units unavoidably can be exist, such as with bad etch, foreign matter, etcetera. The position information of the defect substrate units are generally pre labeled by the manufacturers of substrates or can be acquired by detection. In this embodiment, the substrate unit 101 is supposed to be a defect one.

The acquired position information will be fetched in the subsequent steps by kinds of process apparatus to avoid performing the processes to these defect substrate units and save process cost.

Step 110, delivering the position information to a process management system. The process management system is a dedicated system for allocating correlations between the respective processes and integrating different processes. The system is capable of achieving the communication among kinds of apparatuses.

Step 120, confirming whether a proportion of the amount of the defect substrate units in the substrate exceeds a predetermined threshold or not. The judgment result is: if the proportion does not exceed the threshold, then the printing operation is keeping to be performed, if the proportion exceeds the threshold, then printing operation to the substrate is stopped. This step is an optional step. The purpose is to control the productive efficiency of the production line in advance. If the amount of the defect substrate units is excessive, then only few numbers of the defect substrate units is going to be processed in the subsequent processes and it is beneficial to raise the productive efficiency. Therefore, performing no subsequent processes can be ensured under circumstance of excessive defect substrate units with the setting of the threshold.

Next, Steps 131 to 133 are the printing step and detecting step to the substrate.

Step 131, the process management system delivers the position information to a first alignment film printing apparatus 12 and a first detection apparatus. In this step, the first alignment film printing apparatus 12 is employed for alignment film printing operation to the substrate 10. The first detection apparatus is employed for detecting the process quality (not shown) of the first alignment film printing apparatus 12. The process management system at least delivers the position information of the defect substrate units to the first alignment film printing apparatus 12 to ensure that the alignment film printing operation to the defect substrate units (the substrate unit 101 in this embodiment) is excluded to save cost of the printing material. As being an optional step, the process management system further delivers the position information to the first detection apparatus. Substantially, the process management system also can delivers the position information to the subsequent multiple process apparatuses which need to distinguish the defect substrate units to ensure that these process apparatuses exclude the processes to the defect substrate unit 101. Accordingly, the essence of that the process management system delivers the position information to the subsequent multiple process apparatuses should be included in the field of the technical concept described in the present invention.

Step 132, the first alignment film printing apparatus 12 excludes the alignment film printing operation to the defect substrate unit 101 according to the acquired position information. The first alignment film printing apparatus 12 is going to perform the alignment film printing operation to the surface of the substrates units 101˜104 of the substrate 10 in this step. In prior arts, the first alignment film printing apparatus 12 performed the alignment film printing operation to all the substrates units 101˜104 and causes the wastage of the polyimide material, etcetera. In this embodiment, first alignment film printing apparatus 12 has been delivered with the position information of the defect substrate unit 101. Therefore, the alignment film printing operation performed to the defect substrate unit 101 is excluded and the printing material is saved.

Step 133, the first detection apparatus excludes the detection to the defect substrate units. This step is an optional step. If the process management system delivers the position information of the defect substrate unit 101 to the subsequent multiple process apparatuses including the detection apparatus, the detection apparatus and other multiple process apparatuses do not have to perform the detection to the defect substrate unit 101. Not only the detection time can be saved but the false alert generated by the detection apparatus due to misjudging the low yield rate of the printing process can be prevented.

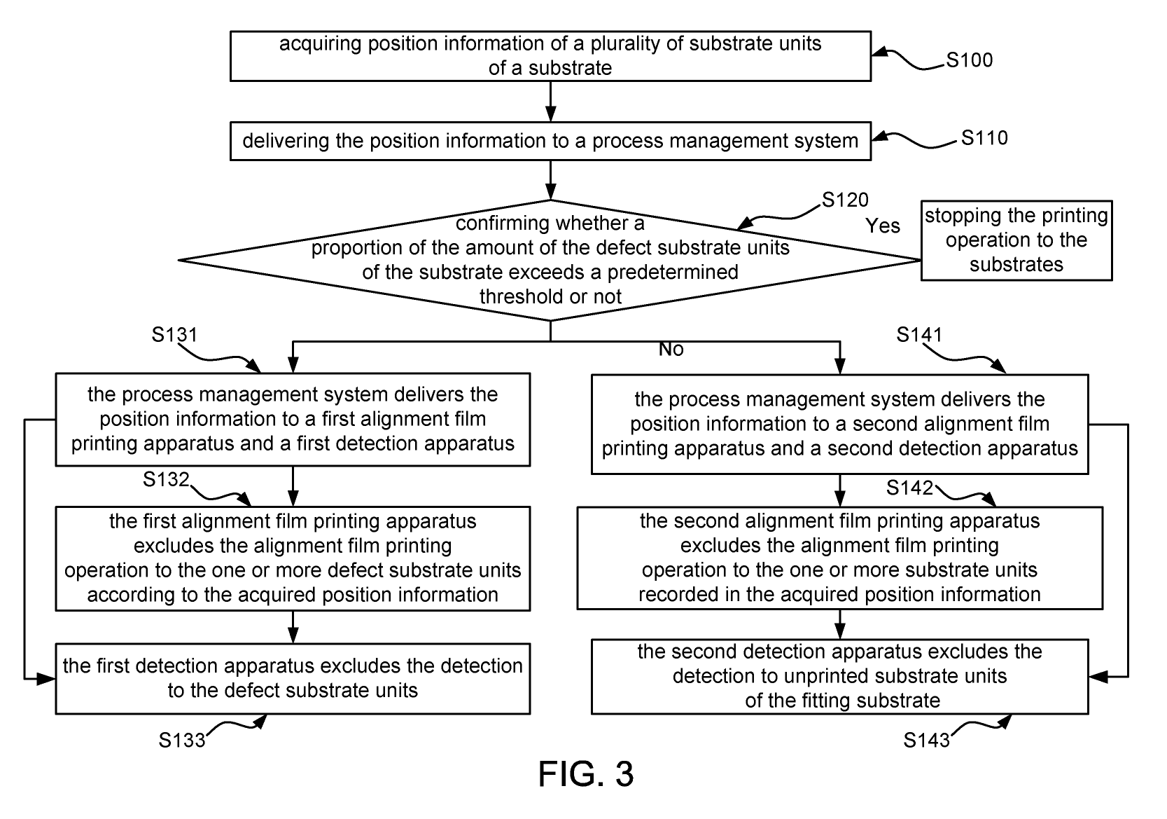

Next, introduced is the second specific embodiment of the method according to the present invention. FIG. 3 shows a flowchart of this specific embodiment of the method according to the present invention. The method comprises the steps below: Step 100, acquiring position information of one or more defect substrate units of the substrate; Step 110, delivering the position information to a process management system; Step 120, confirming whether a proportion of the amount of the defect substrate units in the substrate exceeds a predetermined threshold or not; Step 131, the process management system delivers the position information to a first alignment film printing apparatus and a first detection apparatus; Step 132, the first alignment film printing apparatus excludes the alignment film printing operation to the one or more defect substrate units according to the acquired position information; Step 133, the first detection apparatus excludes the detection to the defect substrate units; Step 141, the process management system delivers the position information to a second alignment film printing apparatus and a second detection apparatus; Step 142, the second alignment film printing apparatus excludes the alignment film printing operation to the one or more substrate units recorded in the acquired position information; Step 143, the second detection apparatus excludes the detection to unprinted substrate units of the fitting substrate.

The aforementioned Steps 100 to 133 are the same as those in the first specific embodiment, the introductions are omitted hereby.

Steps 141 to 143 are the printing step and detecting step to the fitting substrate which are preferable steps. The apparatus for performing the alignment film printing operation to the fitting substrate is the same as that shown in FIG. 2, therefore, figure is omitted hereby.

In the manufacture processes of the LCD panel, two substrates are printed individually and the two substrates are attached with each other, so called fitting up process. Each of the two substrates for fitting up process is a fitting substrate to the other. If one of the two fitting up substrates comprises a defect substrate unit, and a corresponding substrate unit of the other fitting up substrate is a nondefective one, the product with the two fitting up substrate units obviously becomes a defect one. The purpose of Steps 141 to 143 is to prevent the substrate unit of the fitting substrate corresponding to the defect substrate unit is performed with the alignment film printing operation. Accordingly, the printing material cost and the detection time can be saved.

Step 141, the process management system delivers the position information to a second alignment film printing apparatus and a second detection apparatus. This step is synchronously performed with Step 131. In this step, the second alignment film printing apparatus is employed for alignment film printing operation to the fitting substrate. The second detection apparatus is employed for detecting the process quality of the second alignment film printing apparatus.

Step 142, the second alignment film printing apparatus excludes the alignment film printing operation to the one or more substrate units recorded in the acquired position information. In this step, because the substrate unit at the position of the substrate is a defect one, no matter the corresponding substrate unit of the fitting substrate is defective or not, the printing operation to the corresponding substrate unit of the fitting substrate becomes meaningless.

Step 143, the second detection apparatus excludes the detection to unprinted substrate units of the fitting substrate. Similar to Step 133, this step not only can save the detection time but also prevent the false alert generated by the detection apparatus due to misjudging the low yield rate of the printing process.

The benefits of foregoing second embodiment are considerations of the printing step of the fitting substrate in advance. Because no matter the corresponding substrate unit of the fitting substrate is defective or not, the substrate unit at the position of the other substrate is confirmed as a defect one, the printing operation to the corresponding substrate unit of the fitting substrate becomes meaningless. Therefore, the second specific embodiment can save the process cost in advance.

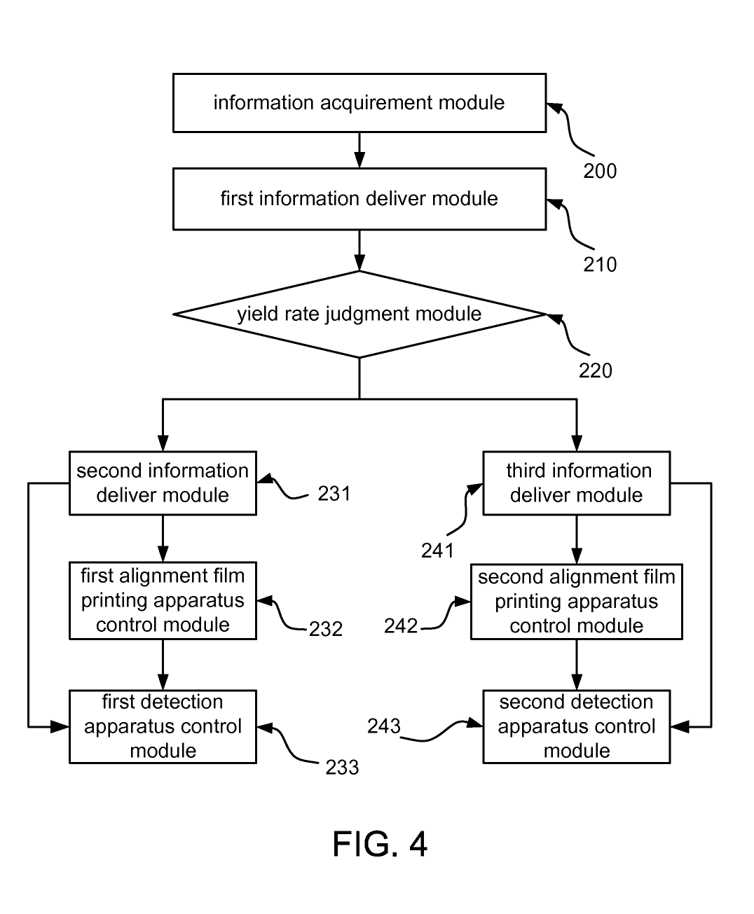

Then, introduced is the specific embodiment of the device according to the present invention in conjunction with the figure. FIG. 4 shows a structure diagram of the device according to the present invention. The device comprises an information acquirement module 200, a first information deliver module 210, a yield rate judgment module 220, a second information deliver module 231, a first alignment film printing apparatus control module 232, a first detection apparatus control module 233, a third information deliver module 241, a second alignment film printing apparatus control module 242 and a second detection apparatus control module 243.

After the information acquirement module acquires position information of defect substrate units. The position information is delivered to the first information deliver module 210. After the yield rate judgment module 220 confirms the yield rate. The position information is delivered to the second information deliver module 231 and the third information deliver module 241. The second information deliver module 231 delivers the position information to the first alignment film printing apparatus control module 232 and the first detection apparatus control module 233 for performing printing operation and detection to the substrate; the third information deliver module 241 delivers the position information to the second alignment film printing apparatus control module 242 and the second detection apparatus control module 243 for performing printing operation and detection to the fitting substrate corresponding to the substrate.

Specifically, the information acquirement module 200 is employed for acquiring position information of one or more defect substrate units of the substrate. The substrate comprises a plurality of substrate units arrayed therein. The first information deliver module is employed for delivering the position information to a process management system. The yield rate judgment module 220 is employed for confirming whether a proportion of the amount of the defect substrate units of the substrate exceeds a predetermined threshold or not. If the proportion does not exceed the threshold, then keeping performing the alignment film printing operation to the substrate and if the proportion exceeds the threshold, then stopping performing the alignment film printing operation to the substrate.

The second information deliver module 231 is employed for delivering the position information to first alignment film printing apparatus and the first detection apparatus. The first alignment film printing apparatus is employed for performing an alignment film printing operation to the substrate. The first detection apparatus is employed for detecting the process quality of the first alignment film printing apparatus.

The first alignment film printing apparatus control module 232 is employed for controlling the first alignment film printing apparatus to exclude the alignment film printing operation to the defect substrate units according to the acquired position information in the step of performing alignment film printing operation to the substrate.

The first detection apparatus control module 233 is employed for controlling the first detection apparatus to exclude the detection to the defect substrate units.

The third information deliver module 241 is employed for delivering the position information to a second alignment film printing apparatus. The second alignment film printing apparatus is employed for performing an alignment film printing operation to a fitting substrate corresponding to the substrate. The second detection apparatus is employed for detecting the process quality of the second alignment film printing apparatus.

The second alignment film printing apparatus control module 242 is employed for excluding the alignment film printing operation to the substrate units recorded in the acquired position information when the second alignment film printing apparatus performs the alignment film printing operation to the fitting substrate.

The second detection apparatus control module 243 is employed for excluding the detection to unprinted substrate units of the fitting substrate.

The fourth information deliver module (not shown) is employed for the process management system to deliver the position information of the defect substrate units to the subsequent multiple process apparatuses to exclude processes to the defect substrate units.

Please refer to the first and second specific embodiments of the related method as aforementioned for more detail introductions.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. An alignment film printing method of LCD panel, characterized in comprising:
acquiring position information of a plurality of substrate units of a substrate, and the plurality of substrate units arrayed in the substrate comprises one or more defect substrate units;
delivering the position information to a process management system;
delivering the position information to a first alignment film printing apparatus, a second alignment film printing apparatus, a first detection apparatus and a second detection apparatus by the process management system, and the first alignment film printing apparatus is employed for performing an alignment film printing operation to the substrate, and the first detection apparatus is employed for detecting the process quality of the first alignment film printing apparatus, and the second alignment film printing apparatus is employed for performing an alignment film printing operation to a fitting substrate corresponding to the substrate, and the second detection apparatus is employed for detecting the process quality of the second alignment film printing apparatus;
excluding the alignment film printing operation to the defect substrate units according to the acquired position information in the step of performing the alignment film printing operation to the substrate with the first alignment film printing apparatus;
excluding the detection to the defect substrate units according to the acquired position information in the step of detecting the substrate with the first detection apparatus;
excluding the alignment film printing operation to the defect substrate units according to the acquired position information in the step of performing the alignment film printing operation to the fitting substrate with the second alignment film printing apparatus; and
excluding the detection to the defect substrate units according to the acquired position information in the step of detecting the fitting substrate with the second detection apparatus.

2. An alignment film printing method of LCD panel, characterized in comprising:
acquiring position information of a plurality of substrate units of a substrate, and the plurality of substrate units arrayed in the substrate comprises one or more defect substrate units;
delivering the position information to a process management system;
delivering the position information to a first alignment film printing apparatus by the process management system, and the first alignment film printing apparatus is employed for performing an alignment film printing operation to the substrate; and
excluding the alignment film printing operation to the defect substrate units according to the acquired position information in the step of performing the alignment film printing operation to the substrate with the first alignment film printing apparatus.

3. The alignment film printing method of LCD panel of claim 2, characterized in that after the process management system obtains the position information, the method further comprises a step of:
confirming whether a proportion of the amount of the defect substrate units in the substrate exceeds a predetermined threshold or not, and if the proportion does not exceed the threshold, then keeping performing the alignment film printing operation to the substrate, if the proportion exceeds the threshold, then stopping performing the alignment film printing operation to the substrate.

4. The alignment film printing method of LCD panel of claim 2, characterized in that in the step of delivering the position information to the first alignment film printing apparatus by the process management system, the method further comprises a step of:
delivering the position information to a first detection apparatus employed for detecting the process quality of the first alignment film printing apparatus for the first detection apparatus to exclude the detection to the defect substrate units.

5. The alignment film printing method of LCD panel of claim 2, characterized in that after the process management system obtains the position information, the method further comprises steps of:
delivering the position information to a second alignment film printing apparatus, employed for performing an alignment film printing operation to a fitting substrate corresponding to the substrate; and
excluding the alignment film printing operation to the corresponding substrate units of the fitting substrate according to the acquired position information in the step of performing the alignment film printing operation to the fitting substrate with the second alignment film printing apparatus.

6. The alignment film printing method of LCD panel of claim 5, characterized in that in that in the step of delivering the position information to the second alignment film printing apparatus by the process management system, the method further comprises a step of:
delivering the position information to a second detection apparatus employed for detecting the process quality of the second alignment film printing apparatus for the second detection apparatus to exclude the detection to unprinted substrate units of the fitting substrate.

7. The alignment film printing method of LCD panel of claim 2, characterized in further comprising a step of:
delivering the position information of the defect substrate units to subsequent multiple process apparatuses capable of excluding processes to the defect substrate units.

8. The alignment film printing method of LCD panel of claim 2, characterized in that material of the alignment film is polyimide.

9. An alignment film printing device of LCD panel, characterized in comprising:
an information acquirement module, acquiring position information of a plurality of substrate units of a substrate, and the plurality of substrate units arrayed in the substrate comprises one or more defect substrate units;
a first information deliver module, delivering the position information to a process management system;
a second information deliver module, employed for the process management system to deliver the position information to a first alignment film printing apparatus and the first alignment film printing apparatus is employed for performing an alignment film printing operation to the substrate; and
a first alignment film printing apparatus control module, controlling the first alignment film printing apparatus to exclude the alignment film printing operation to the defect substrate units according to the acquired position information.

10. The alignment film printing device of LCD panel of claim 9, characterized in further comprising a yield rate judgment module between the first information deliver module and the second information deliver module, and the yield rate judgment module is employed for confirming whether a proportion of the amount of the defect substrate units in the substrate exceeds a predetermined threshold or not, and if the proportion does not exceed the threshold, then keeping performing the alignment film printing operation to the substrate, if the proportion exceeds the threshold, then stopping performing the alignment film printing operation to the substrate.

11. The alignment film printing device of LCD panel of claim 9, characterized in that the second information deliver module further progresses a step of:
delivering the position information to a first detection apparatus employed for detecting the process quality of the first alignment film printing apparatus; and
the first alignment film printing apparatus further comprises a first detection apparatus control module, controlling the first detection apparatus to exclude the detection to the defect substrate units.

12. The alignment film printing device of LCD panel of claim 9, characterized in that after the first information deliver module, the device further comprises:
a third information deliver module, employed for delivering the position information to a second alignment film printing apparatus, employed for performing an alignment film printing operation to a fitting substrate corresponding to the substrate; and
a second alignment film printing apparatus control module, excluding the alignment film printing operation to the corresponding substrate units of the fitting substrate according to the acquired position information in the step of performing the alignment film printing operation to the fitting substrate with the second alignment film printing apparatus.

13. The alignment film printing device of LCD panel of claim 12, characterized in that the third information deliver module further progresses a step of:
delivering the position information to a second detection apparatus, employed for detecting the process quality of the second alignment film printing apparatus; and
the second alignment film printing apparatus further comprises a second detection apparatus control module to exclude the detection to unprinted substrate units of the fitting substrate.

14. The alignment film printing device of LCD panel of claim 9, characterized in further comprising:
a fourth information deliver module, employed for delivering the position information of the defect substrate units to subsequent multiple process apparatuses capable of excluding processes to the defect substrate units.

15. The alignment film printing device of LCD panel of claim 9, characterized in that material of the alignment film is polyimide.
